(19) United States
(12) Patent Application Publication
(10) Pub. No.: US 2009/0227048 A1
(43) Pub. Date: Sep. 10, 2009

(54) METHOD FOR DIE BONDING HAVING PICK-AND-PROBING FEATURE

(75) Inventors: Li-Chih FANG, (US); Wen-Jeng Fan, (US); Nan-Chun Lin, (US)

Correspondence Address: Muncy, Geissler, Olds & Lowe, PLLC, P.O. BOX 1364, FAIRFAX, VA, 22038-1364, US

(73) Assignee: Powertech Technology Inc.

(21) Appl. No.: 12/042,093

(22) Filed: Mar. 4, 2008

(51) Int. Cl. H01L 21/66

(52) U.S. Cl. 438/15; 257/E21.53

(57) ABSTRACT

Disclosed is a die-bonding method having pick-and-probe features after wafer sawing where at least a die is probed and sorted according to different grades during a pick-and-place step performed after wafer sawing. A suction nozzle having a plurality of probes is utilized to probe the electrical terminals of the die. After picking, the suction nozzle is moved on a common moving path and the picked die is tested through the suction nozzle. The picked-and-probed die is moved and die-bonded to a die carrier loaded in a corresponding one of a plurality of die-bonding areas by moving the Suction nozzle on a chosen sorting path. Therefore, the die is probed and sorted during die-bonding processes. Higher graded dice at a same level are assembled on a same die carrier to form a higher graded semiconductor package.

### FIELD OF THE INVENTION

The present invention relates to fabrication technologies of semiconductor devices about a die-bonding method after wafer sawing, especially to a die-bonding method with pick-and-probe features after wafer sawing.

### BACKGROUND OF THE INVENTION

In semiconductor front-end fabrication, the process flow is IC design, wafer fabrication, wafer probing, and wafer sawing. After wafer probing and wafer sawing processes, individual IC dice are formed for semiconductor packaging.

Whether the electrical performance and characteristics of each IC die have met the design specifications are confirmed by testers and probe cards to probe every die on a wafer. The probes of a probe card mounted on the tester head of a tester keep in contact with the bonding pads of a die to test its electrical characteristics and then failed dice will be marked. After wafer sawing, a wafer is diced into a plurality of individual dice where some of the dice with marks are scrapped without proceeding to the sequent packaging processes to save unnecessary packaging costs. Moreover; multiple wafer probing is necessary to ensure all the dice before packaging are known good dies (KGD) to avoid yield loss due to stacking or assembling of in multiple dice such as multi-die module, MCM, or system-in-package, SIP.

Generally speaking, the first step in semiconductor packaging is die bonding or die attaching performed after wafer probing and wafer sawing. After wafer probing and wafer sawing, different grades or different types of individual dice are sorted and stored at different die trays or die carrier tapes before die bonding. Then, individual dice are picked from the die trays or die carrier tapes by a suction nozzle then die bonded to die carriers which is the most time consuming step and greatly reduces the productivity. If die bonding is performed right after wafer sawing, higher graded dies and lower graded dies may easily be mixed in a die carrier, especially in multi-die package applications. If different graded dice are packaged in the same semiconductor package, then the overall operation frequency will base on the die with the lowest grade leading to lower electrical performance of the semiconductor packages. Moreover, the yield and productivity of semiconductor packages with higher grades are reduced leading to decrease of revenue.

### SUMMARY OF THE INVENTION

The main purpose of the present invention is to provide a die-bonding method with pick-and-probe features after wafer sawing where die probing and sorting are performed at the same time as picking the dice during die bonding processes without extra sorting steps to reduce processing time. Moreover, higher graded dice and lower graded dice are not mixed together in the same semiconductor packages leading to better productivity of different graded semiconductor packages.

The second purpose of the present invention is to provide a die-bonding method with pick-and-probe features after wafer sawing to reduce particle contaminations of bonding pads during wafer probing to keep wafers clean.

The third purpose of the present invention is to provide a die-bonding method with pick-and-probe features after wafer sawing to screen out bad dies during die-bonding processes according to the sorting results to eliminate the risk of probing or sorting errors to maintain higher packaging yields.

According to the present invention, a die-bonding method with pick-and-probe features after wafer sawing is revealed. Firstly, at least a die is provided, having a plurality of electrical terminals where the die is loaded in a loading area. Additionally, a plurality of die carriers are loaded in a plurality of die-bonding areas where the die-bonding areas are sorted for different graded dice. Then, the die is picked by a suction nozzle where the suction nozzle has a plurality of probes to contact the electrical terminals of the die. The die is tested and moved to a corresponding one of the die-bonding areas through the suction nozzle during a pick-and-place step. Moreover, the suction nozzle is working in a plurality of sorting paths from the loading area to the die-bonding areas. Then, according to the sorting results, a corresponding one of the sorting paths is chosen so that the die is moved to the corresponding die-bonding area and is bonded onto a die carrier in the corresponding die-bonding area.

### DESCRIPTION OF THE DRAWINGS

FIG. 1 shows operation processes of dice moved on a plurality of sorting paths of the die-bonding method with pick-and-probe features after wafer sawing according to the preferred embodiment of the present invention.

FIG. 2 shows a side view at the loading area illustrating the die-bonding method with pick-and-probe features after wafer sawing according to the preferred embodiment of the present invention.

### DETAIL DESCRIPTION OF THE INVENTION

Please refer to the attached drawings, the present invention will be described by means of embodiments below.

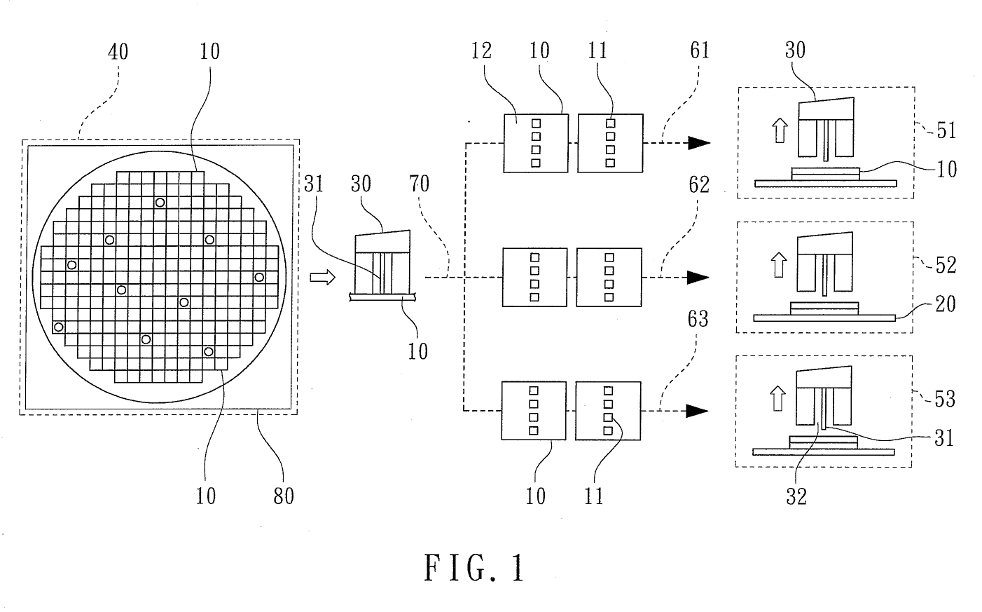

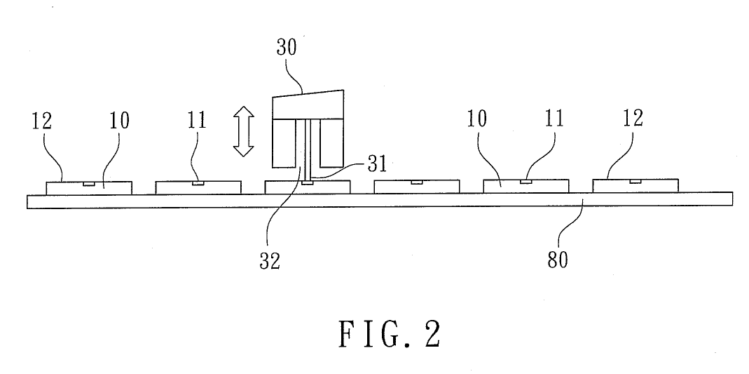

According to the first embodiment of the present invention, a die-bonding method with pick-and-probe features after wafer sawing comprises the following steps. As shown in FIG. 1, firstly, at least a die 10 is provided where the dice 10 are taken from a singulated wafer. As shown in FIGS. 1 and 2, a plurality of electrical terminals 11 are disposed on the active surface 12 of the die 10. A die-bonding equipment, also known as a die bonder, includes at least a suction nozzle 30, a loading area 40, a plurality of die-bonding areas 51, 52, and 53, and a plurality of sorting paths 61, 62, and 63. Therein, the die-bonding areas 51, 52, and 53 are graded according to a plurality of different die grades, and the sorting paths 61, 62, and 63 is connected from a common moving path 70 connecting the loading area 40 to the corresponding die-bonding areas 51, 52, and 53.

By choosing an appropriate sorting path 61, 62, or 63, the suction nozzle 30 can move from the loading area 40 optionally to one of the die-bonding areas 51, 52, and 53. In one embodiment, the die grades for sorting the die-bonding areas 51, 52, and 53 are the sorting of DDR2 dice so that the die-bonding areas 51, 52, and 53 are defined as a 533 MHz area, a 667 MHz area, and an 800 MHz area, or preferably, by more die-bonding areas of a 1066 MHz area or/and a scrapped area. However, without any limitations, the die-bonding method according to the present invention can also be implemented in flash memories and other ASIC. The dice 10 are located at the loading area 40. As shown in FIG. 1 and FIG. 2, the dice 10 are loaded in the loading area 40 by attached to a wafer-saw tape 80 or the other method so that die-bonding processes can be performed right after wafer sawing. Some of the dice 10 with marks on the wafer-saw tape 80 are lower graded dice or bad dice such as the dice marked with circles in FIG. 1.

According to the method, a plurality of die carriers 20 are loaded in the plurality of die-bonding areas 51, 52, and 53. In one embodiment, the die carriers 20 are substrates for multi-die packages or for multi-die stacked memory cards. Alternatively, the die carriers 20 can be semiconductor dice 10 to form multi-die module packages.

The die-bonding method includes a pick-and-place step. The suction nozzle 30 is working among the sorting paths 61, 62, and 63 connecting the loading area 40 to the die-bonding areas 51, 52, and 53. Firstly, the suction nozzle 30 moves to the loading area 40 to pick up a die 10 where the suction nozzle 30 has a plurality of probes 31 to probe the electrical terminals 11 of the die, as shown in FIG. 2. After picking Lip the die 10, the functions of the die 10 are tested and the die 10 is moved on the common moving path 70, then one of the sorting paths 61, 62, and 63 is chosen according to the testing result. The die 10 picked by the suction nozzle 30 is moved on the chosen sorting paths 61, 62, or 63 and then bonded onto the corresponding die carrier 20 in the corresponding die-bonding area 51, 52, or 53. Accordingly, different grades of probed dice can be placed to different die-bonding areas 51, 52, and 53 to avoid any waste of sorting materials such as die trays or die carrier tapes and to simplify processing steps.

To be more specific, as shown in FIG. 2, the suction nozzle 30 picks the die 10 in contact with the active surface 12 of the die 10 to probe the electrical terminals 11 of the die 10 by the probes 31. Preferably, the probes 31 of the suction nozzle 30 are formed in the vacuum holes 32 of the suction nozzle 30 where the vacuum holes 32 are connected to a vacuum source such as a vacuum pump by a vacuum tube, not shown in the figure, so that the suction nozzle 30 has a suction force to hold the die 10 and to probe the electrical terminals 11 of the die 10 at the same time. Moreover, the electrical terminals 11 of the die 10 are not be contaminated during probing the die 10 so that the die 10 is kept clean.

As shown in FIG. 1, according to the different grades of the probed dice 10, a corresponding sorting path 61, 62, or 63 of the suction nozzle 30 is chosen, and then the probed die 10 is moved on the chosen sorting path 61, 62, or 63 to the corresponding die-bonding areas 51, 52, or 53 without manually sorted the dice 10 to save processing time. In the present embodiment, the suction nozzle 30 can work along the common moving path 70 connecting the loading area 40 to the sorting path 61, 62, or 63. The step of testing the picked die 10 by the suction nozzle 30 is completed when the suction nozzle 30 is moved on the common moving path 70.

Finally, the probed die 10 is bonded to the corresponding die-bonding areas 51, 52, or 53 by the suction nozzle 30. A die-attaching material can be disposed on the die carrier 20 such as epoxy, silver paste, B-stage paste, or double-sided adhesive P1 tapes. Accordingly, the suction nozzle 30 picks the die 10 from the loading area 40, work in a corresponding sorting path 61, 62, or 63, and die bond the die 10 to the die carrier 20. The die-bonding method according to the present invention includes the pick-and-place step, the testing step, the sorting step and the die bonding step by the operation of the suction nozzle 30.

Therefore, the die-bonding method with pick-and-probe features after wafer sawing according to the present invention can pick, probe, and sort the dice at the same time without extra sorting steps to save processing time. Moreover, there is no chance of mixing the higher graded dice with the lower graded dice on a same die carrier to form an inferior semiconductor package. The productivity of higher graded packages is increased.

The above description of embodiments of this invention is intended to be illustrative and not limiting. Other embodiments of this invention will be obvious to those skilled in the art in view of the above disclosure.

What is claimed is:

1. A die-bonding method with pick-and-probe features after wafer sawing, primarily comprising the steps of:
providing at least a die having a plurality of electrical terminals, wherein the die is loaded in a loading area;
providing a plurality of die carriers loaded in a plurality of die-bonding areas, wherein the die-bonding areas are sorted for different graded dice; and
performing a pick-and-place step by utilizing at least a suction nozzle having a plurality of probes, wherein the pick-and-place step includes:
picking up the die in the loading area wherein the probes probe the electrical terminals of the die at the same time;
testing the picked up die for evaluating its grades and moving the suction nozzle on a common moving path from the loading area toward the die-bonding areas;
choosing a corresponding one of a plurality of sorting paths according to the grade of the die, wherein the sorting paths connect the common moving path to the die-bonding areas respectively;
moving the suction nozzle to the corresponding one of the die-bonding areas; and
bonding the die picked by the suction nozzle to the corresponding die carrier in the corresponding die-bonding area.

2. The method as claimed in claim 1, wherein the step of testing the picked up die is completed and merged during the suction nozzle is moving on the common moving path.

3. The method as claimed in claim 1, wherein the die carrier is a substrate.

4. The method as claimed in claim 1, wherein the die carrier is a semiconductor die.

5. The method as claimed in claim 1, wherein the suction nozzle has a vacuum hole and is in contact with an active surface of the die when picking.

6. The method as claimed in claim 5, wherein the plurality of probes are formed in the vacuum hole of the suction nozzle.

7. The method as claimed in claim 1, wherein the die in the loading area is attached to a wafer saw tape.
